(19) United States
(12) Patent Application Publication
(10) Pub. No.: US 2026/0165017 A1
(43) Pub. Date: Jun. 11, 2026

(54) OLED DISPLAY DEVICE AND COVERING SHEET THEREOF

(71) Applicant: QISDA CORPORATION, Taoyuan City (TW)

(72) Inventor: Chun-Ting Chen, Taoyuan City (TW)

(73) Assignee: QISDA CORPORATION, Taoyuan City (TW)

(21) Appl. No.: 19/390,702

(22) Filed: Nov. 17, 2025

(30) Foreign Application Priority Data
Dec. 9, 2024 (CN) 202411796525.0

(51) Int. Cl. H10K 59/95; H10K 59/80; H10K 102/00

(52) U.S. Cl. CPC H10K 59/95; H10K 59/8722; H10K 59/873; H10K 2102/311

(57) ABSTRACT

An OLED display device includes an OLED panel, a flexible circuit board and a covering sheet. The flexible circuit board is coupled to the OLED panel and extends from a bottom edge of the OLED panel for controlling image display of the OLED panel. The covering sheet includes a frame, a first adhesive tape and a covering component. The frame is disposed at a position corresponding to the bottom edge and avoids the flexible circuit board to form a notch, so as to make the flexible circuit board contained in the notch and make the frame not overlapped with the flexible circuit board in a normal direction of the OLED panel. The first adhesive tape is attached to the frame and matches a shape of the frame. The covering component is attached to the first adhesive tape to cover the bottom edge and the flexible circuit board.

### BACKGROUND OF THE INVENTION

### 1. FIELD OF THE INVENTION

The present invention relates to an OLED display device and a covering sheet thereof, and more specifically, to an OLED display device disposing a frame with a notch at a bottom edge of an OLED panel to provide a tape attachment space for avoiding a flexible circuit board and a covering sheet thereof.

### 2. DESCRIPTION OF THE PRIOR ART

With advancement of display technology, display devices have been developed thinner and lighter. Since traditional CRT (Cathode Ray Tube) display devices, constrained by their internal electronic cavity structure, are over-sized and emit radiation that can harm a user’s eyes, more compact and lightweight OLED (Organic Light-Emitting Diode) display devices have gradually become commonly-used display apparatuses.

In general, a conventional assembly process of an OLED display device involves electrically connecting a flexible circuit board, which controls image display, to a main circuit board. Subsequently, an OLED panel is mounted onto a back plate via a support frame, and a front covering sheet is directly attached to the flexible circuit board by an adhesive attaching method for protection, so as to complete the assembly process of the OLED display device. However, the aforesaid adhesive attaching method cannot ensure uniform adhesive distribution over the front covering sheet. Additionally, this adhesive attaching method also causes adhesive overflow and potential damage to the flexible circuit board during removal of the front covering sheet for maintenance.

### SUMMARY OF THE INVENTION

The present invention provides an OLED display device including an OLED panel, at least one flexible circuit board, and a covering sheet. The at least one flexible circuit board is electrically connected to the OLED panel for controlling image display of the OLED panel. The at least one flexible circuit board extends outward from a bottom edge of the OLED panel in a first direction, wherein the first direction is perpendicular to a normal direction of the OLED panel. The covering sheet includes a frame, a first adhesive tape, and a covering component. The frame is disposed at a position corresponding to the bottom edge. The frame avoids the at least one flexible circuit board to form a notch, to make the flexible circuit board contained in the notch and make the frame not overlapped with the at least one flexible circuit board in the normal direction of the OLED panel. The first adhesive tape is attached to the frame and matches a shape of the frame. The covering component is attached to the first adhesive tape to cover the bottom edge and the at least one flexible circuit board.

The present invention further provides a covering sheet applied to covering at least one flexible circuit board of an OLED display device. The at least one flexible circuit board extends outward from a bottom edge of an OLED panel of the OLED display device in a first direction perpendicular to a normal direction of the OLED panel. The covering sheet includes a frame, a first adhesive tape, and a covering component. The frame is disposed at a position corresponding to the bottom edge. The frame avoids the at least one flexible circuit board to form a notch, to make the at least one flexible circuit board contained in the notch and make the frame not overlapped with the at least one flexible circuit board in the normal direction. The first adhesive tape is attached to the frame and matches a shape of the frame. The covering component is attached to the first adhesive tape to cover the bottom edge and the at least one flexible circuit board.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an OLED display device according to an embodiment of the present invention.

FIG. 2 is a partially-enlarged exploded diagram of the OLED display device in FIG. 1.

FIG. 3 is a partially-enlarged diagram of an OLED panel and a flexible circuit board in FIG. 2 from another viewing angle.

FIG. 4 is a partially-enlarged diagram of a frame in FIG. 2 being disposed on a back plate and avoiding the flexible circuit board.

FIG. 5 is a diagram of a first adhesive tape being attached to the frame in FIG. 4.

FIG. 6 is a diagram of a support plate being attached to the first adhesive tape in FIG. 5.

FIG. 7 is a diagram of a second adhesive tape being attached to the support plate in FIG. 6.

FIG. 8 is a partial cross-sectional diagram of the OLED display device in FIG. 1 along a cross-sectional line A-A.

### DETAILED DESCRIPTION

The present invention will now be described more specifically with reference to the following embodiments and the accompanying drawings. Other advantages and effects of the present invention can be easily understood by a person ordinarily skilled in the art in view of the detailed descriptions and the accompanying drawings. The present invention can be implemented or applied to other different embodiments. Certain aspects of the present invention are not limited by the particular details of the examples illustrated herein. Without departing from the spirit and scope of the present invention, the present invention will have other modifications and changes. It should be understood that the appended drawings are not necessarily drawn to the scale and configuration of each component (e.g., structural designs and thickness ratios of frame/tape/support plate) in the drawings is merely illustrative, not presenting an actual condition of the embodiments.

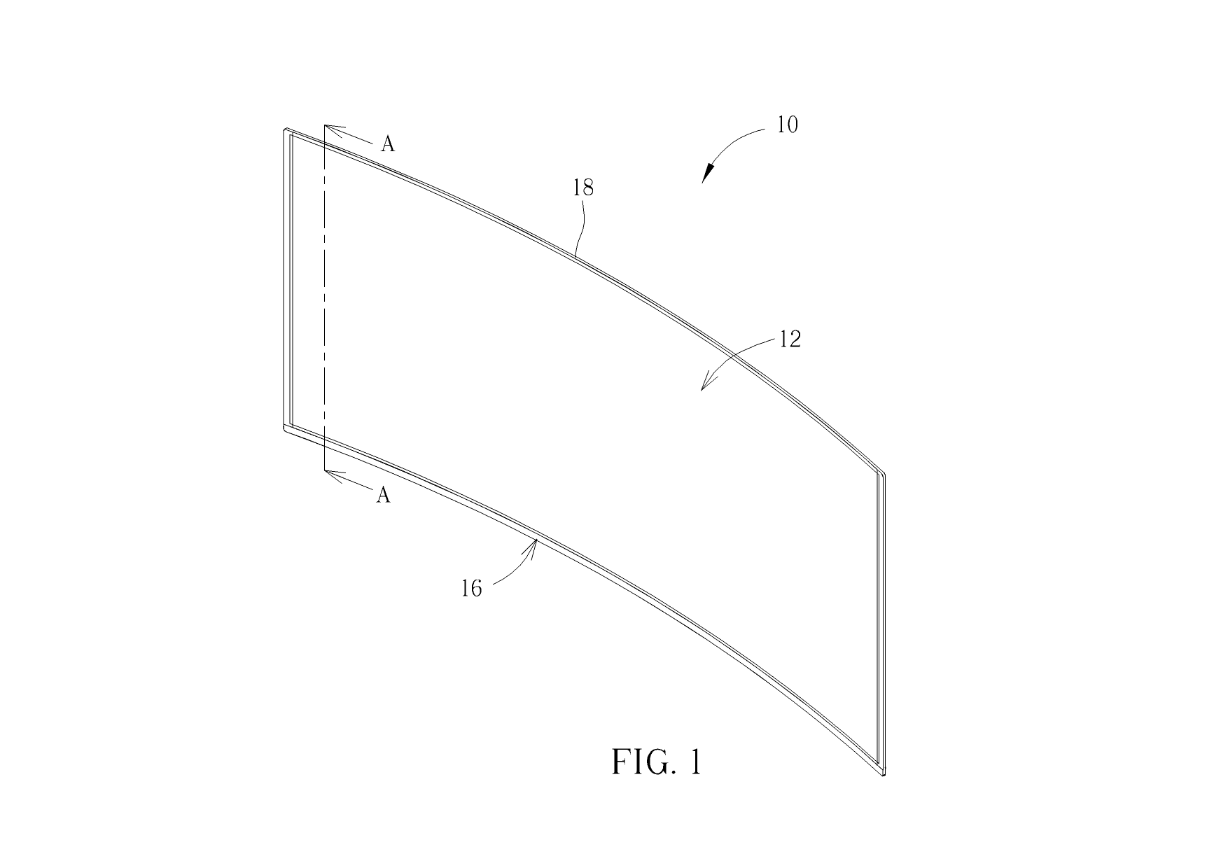

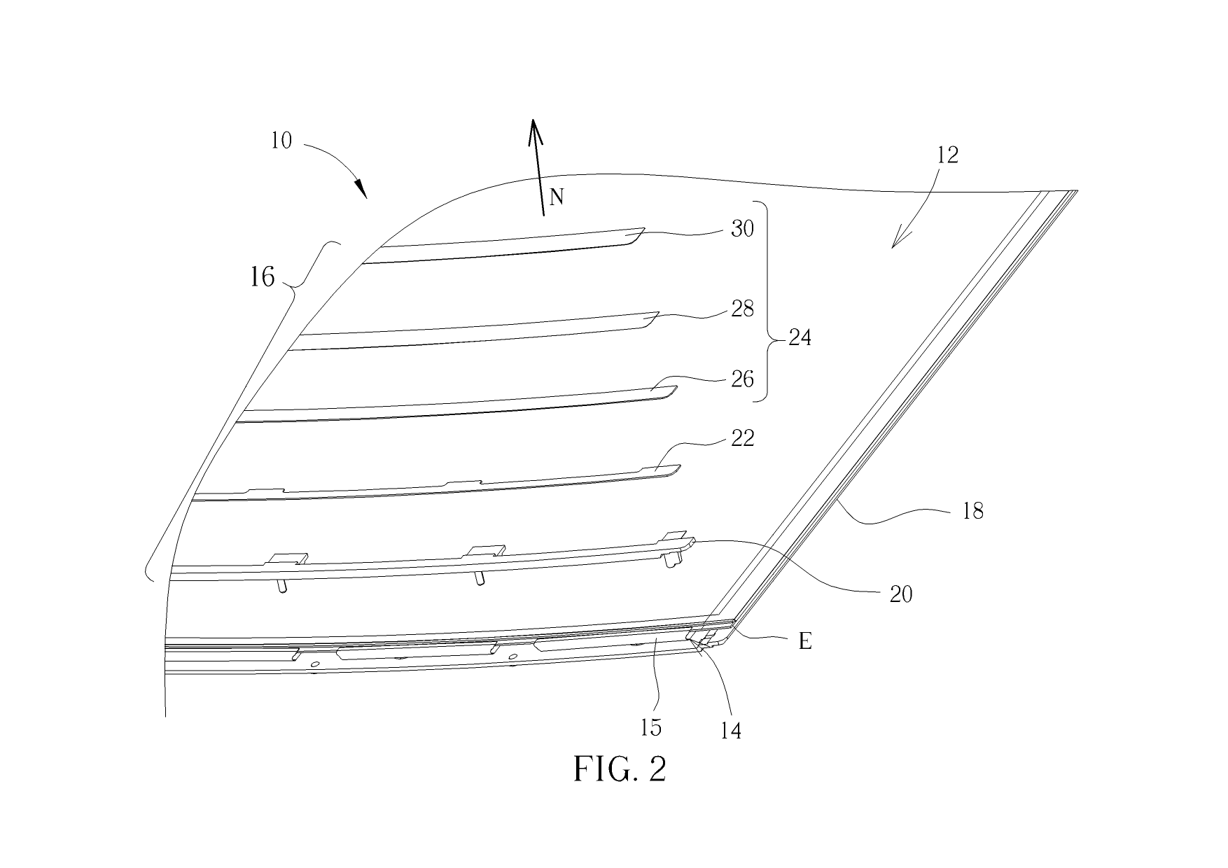

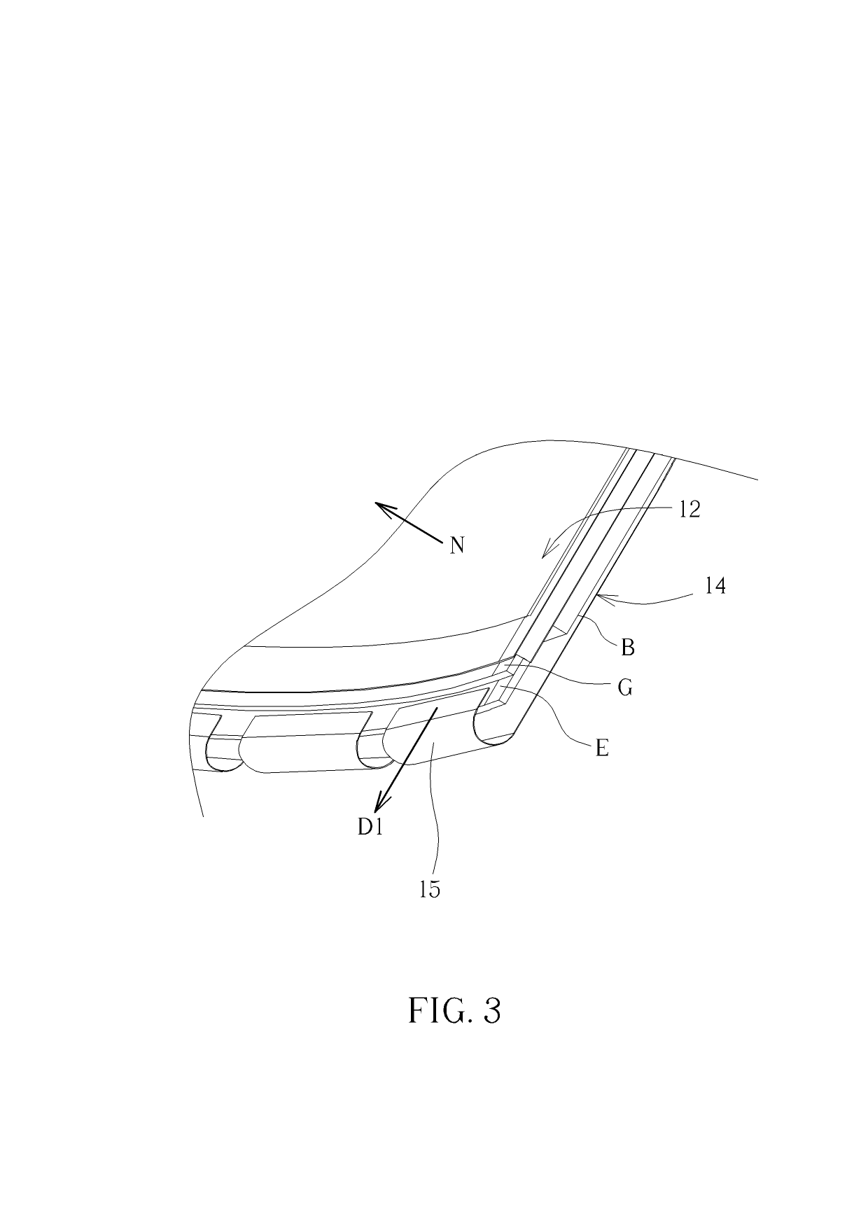

Please refer to FIGS. 1, FIG. 2, and FIG. 3. FIG. 1 is a diagram of an OLED display device 10 according to an embodiment of the present invention. FIG. 2 is a partially-enlarged exploded diagram of the OLED display device 10 in FIG. 1. FIG. 3 is a partially-enlarged diagram of an OLED panel 12 and a flexible circuit board 14 in FIG. 2 from another viewing angle. As shown in FIGS. 1, FIG. 2, and FIG. 3, the OLED display device 10 of the present invention includes the OLED panel 12, at least one flexible circuit board 14 (three shown in FIG. 2, but not limited thereto, meaning that the number of flexible circuit boards could vary depending on the actual manufacturing requirements of the OLED display device 10), and a covering sheet 16. The flexible circuit board 14 could preferably adopt a COF (Chip-On-Film) process (but not limited thereto) to achieve the effect that the flexible circuit board 14 can be bent. The flexible circuit board 14 is electrically connected to the OLED panel 12 for controlling image display of the OLED panel 12 (the related description for the circuit board manufacturing process and the light emitting design of the OLED panel 12 could be commonly seen in the prior art and omitted herein) and extends outward from a bottom edge E of the OLED panel 12 in a first direction D1. As shown in FIG. 3, the first direction D1 is perpendicular to a normal direction N of the OLED panel 12, the flexible circuit board 14 is bent from the OLED panel 12 toward a back surface B of the OLED panel 12 to form a folded board portion 15 (but not limited thereto), and the folded board portion 15 is attached to the back surface B, thereby saving mounting space occupied by the flexible circuit board 14 within the OLED display device 10 and achieving the thinning and narrow-bezel effect. Additionally, as shown in FIGS. 1 and FIG. 2, the OLED display device 10 could further include a back plate 18 (but not limited thereto). The back plate 18 contains the OLED panel 12 for external casing integration and internal structural support of the OLED display device 10.

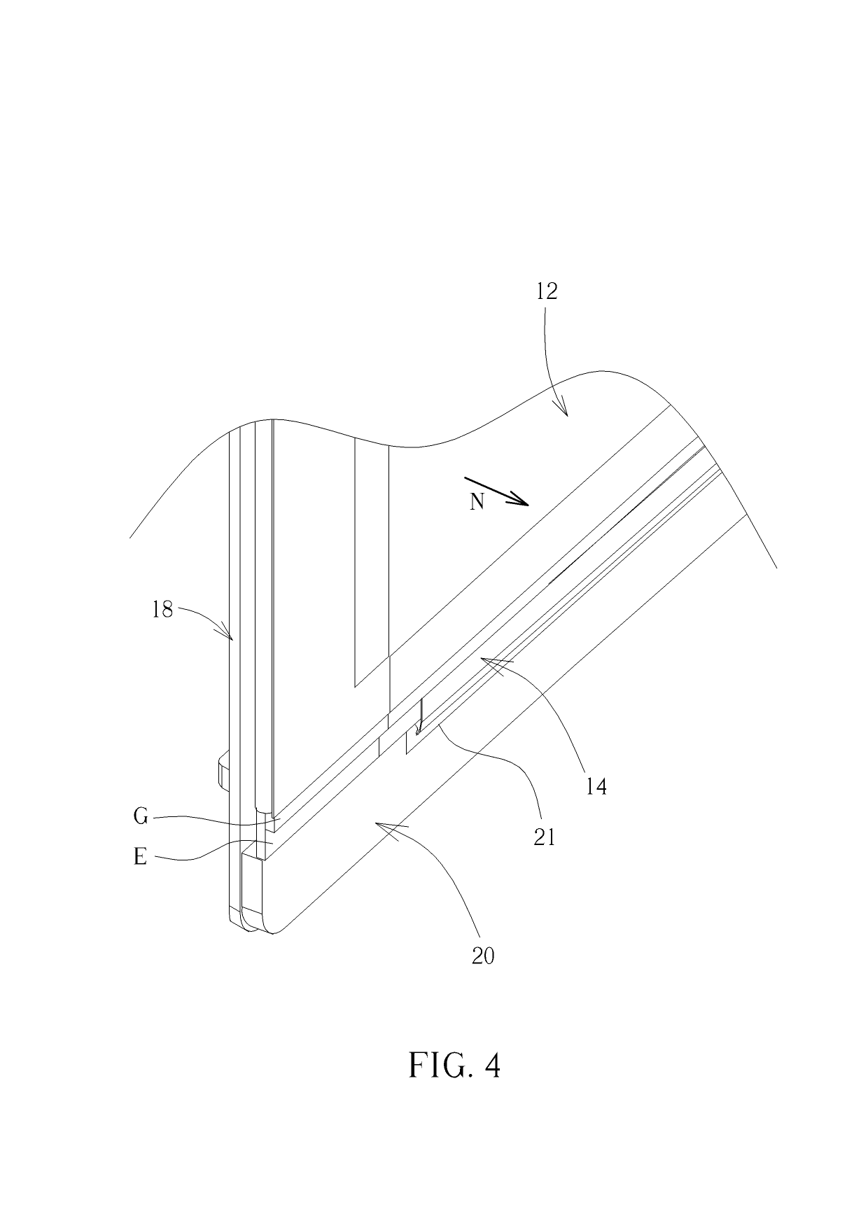

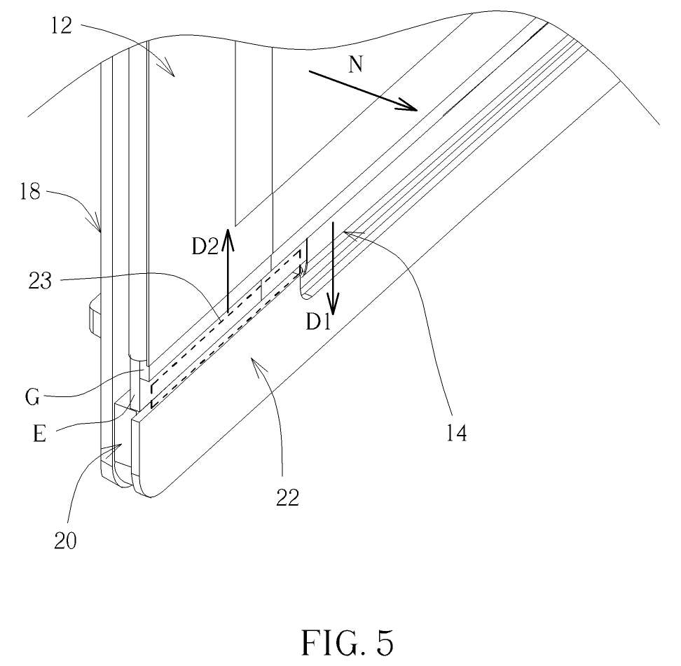

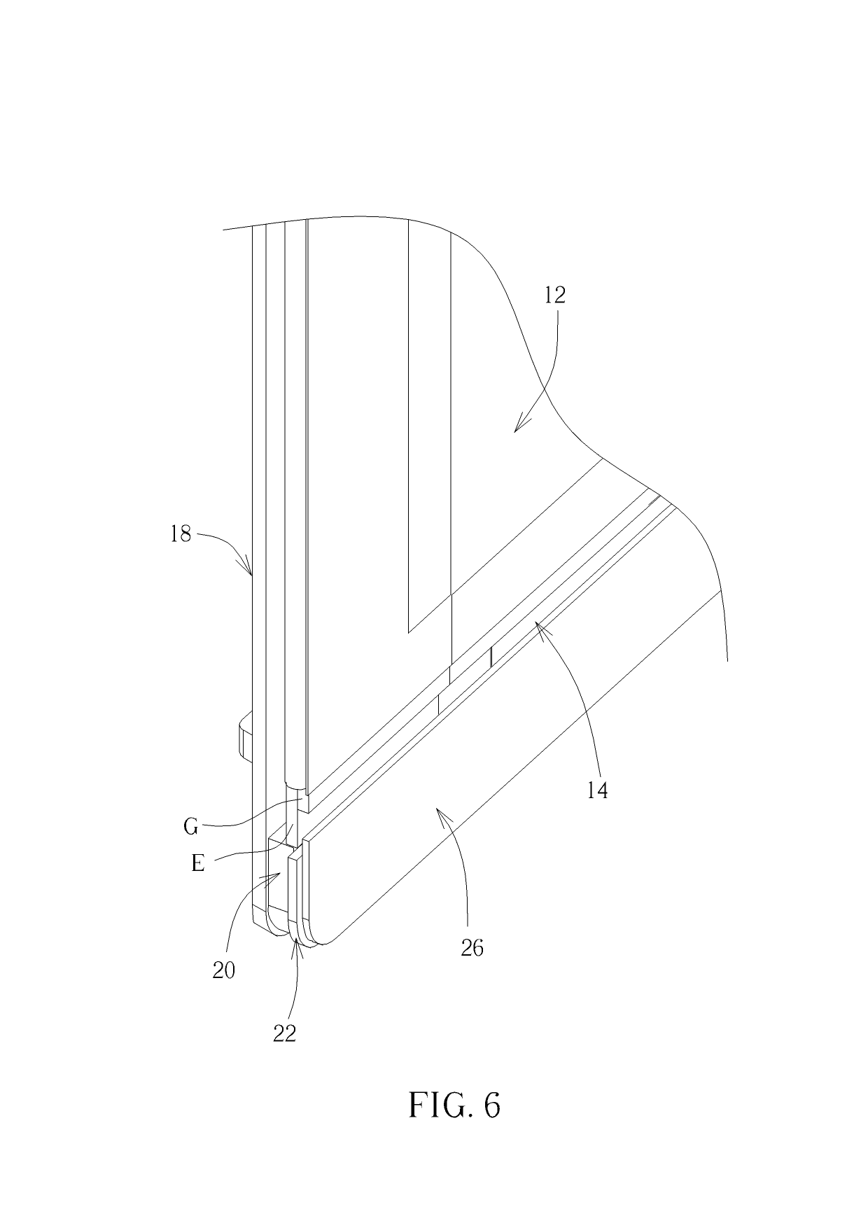

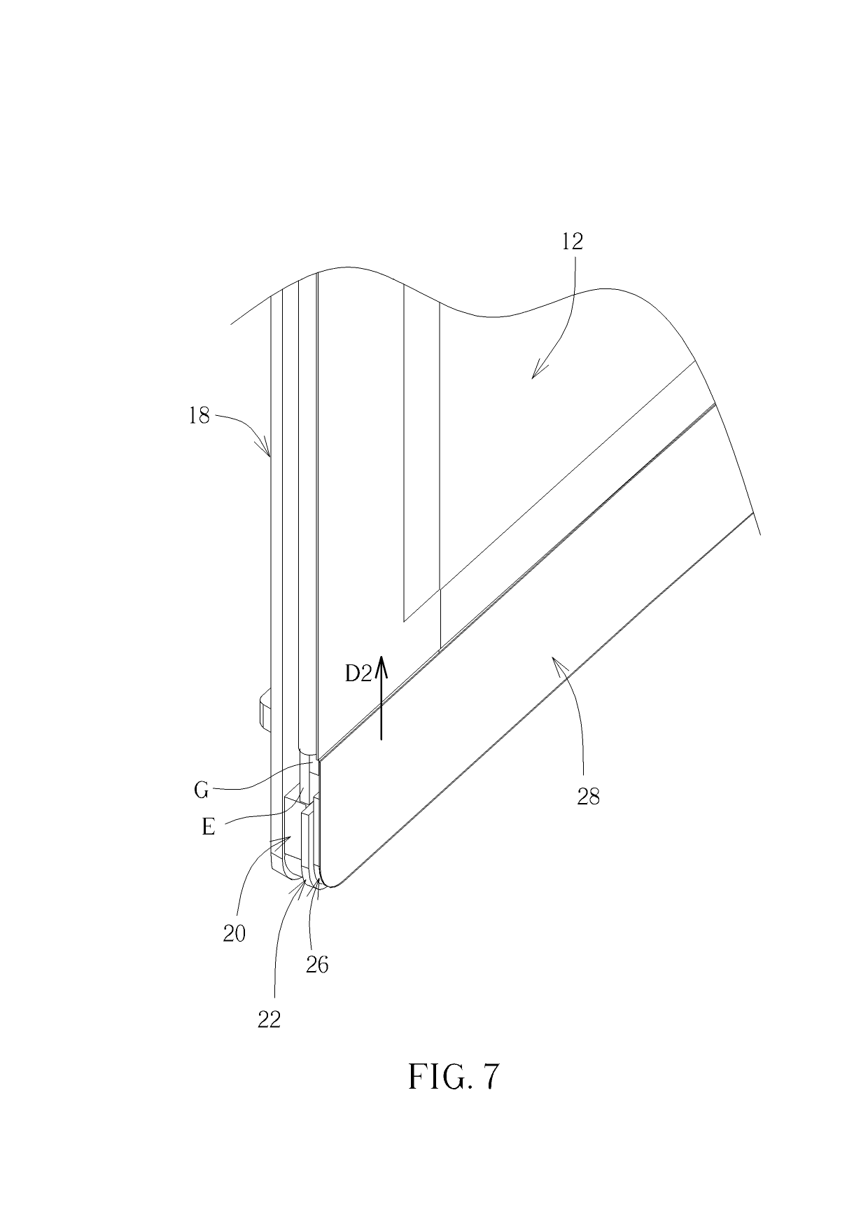

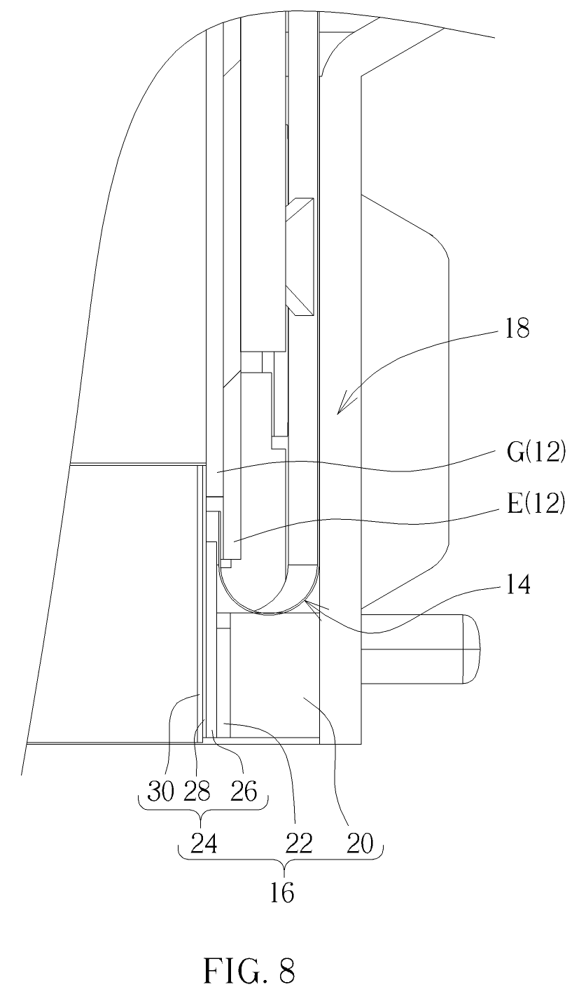

Please refer to FIGS. 1-8. FIG. 4 is a partially-enlarged diagram of the frame 20 in FIG. 2 being disposed on the back plate 18 and avoiding the flexible circuit board 14. FIG. 5 is a diagram of a first adhesive tape 22 being attached to the frame 20 in FIG. 4. FIG. 6 is a diagram of a support plate 26 being attached to the first adhesive tape 22 in FIG. 5. FIG. 7 is a diagram of a second adhesive tape 28 being attached to the support plate 26 in FIG. 6. FIG. 8 is a partial cross-sectional diagram of the OLED display device 10 in FIG. 1 along a cross-sectional line A-A. As shown in FIGS. 1-8, the covering sheet 16 includes the frame 20, the first adhesive tape 22, and a covering component 24. The frame 20 is disposed at a position corresponding to the bottom edge E (e.g., disposed on the back plate 18 corresponding to the bottom edge E) and avoids the folded board portion 15 of the flexible circuit board 14 to form a notch 21, so as to allow the flexible circuit board 14 to be accommodated within the notch 21 and make the frame 20 and the flexible circuit board 14 not overlapped with each other in the normal direction N of the OLED panel 12 (as shown in FIG. 4). Thus, the aforesaid design provides an attachment space within the OLED display device 10 for tape adhesion and avoiding the flexible circuit board 14.

In the aforesaid frame design, the first adhesive tape 22 could match a shape of the frame 20 for attaching to the frame 20 without contacting the flexible circuit board 14 (as shown in FIG. 5), and the covering component 24 could be attached to the first adhesive tape 22 for covering the bottom edge E and the flexible circuit board 14, thereby preventing a user from seeing internal components of the OLED display device 10 during use and consequently enhancing the overall aesthetic effect and user experience of the OLED display device 10. To be more specific, in this embodiment, the covering component 24 could include the support plate 26, the second adhesive tape 28, and a sheet structure 30. The support plate 26 is attached to the first adhesive tape 22 to cover the flexible circuit board 14 (as shown in FIG. 6), the second adhesive tape 28 is attached to the support plate 26 (as shown in FIG. 7), and the sheet structure 30 is attached to the second adhesive tape 28 (as shown in FIG. 8). As such, the support plate 26 can provide a planar support force to the sheet structure 30 for preventing an insufficient support strength of the sheet structure 30 at a position where the sheet structure 30 covers the flexible circuit board 14, thereby improving the overall structural strength of the covering component 24.

To be noted, in practical applications, as shown in FIG. 5, the first adhesive tape 22 could preferably extend toward an area of the bottom edge E not occupied by the flexible circuit board 14 to form a reinforcement adhesive area 23. In such a manner, the first adhesive tape 22 and the reinforcement adhesive area 23 can at least partially surround the flexible circuit board 14 for subsequent attachment of the support plate 26. An extension range of the reinforcement adhesive area 23 is exemplarily illustrated by dashed lines in FIG. 5, but is not limited thereto, meaning that the present invention could also adopt an adhesive reinforcement design in which the reinforcement adhesive area 23 further extends inward in a second direction D2 opposite to the first direction D1 to partially overlap a front panel glass G of the OLED panel 12 adjacent to the bottom edge E. This adhesive reinforcement design ensures that the reinforcement adhesive area 23 and the first adhesive tape 22 can completely or partially surround the flexible circuit board 14, so as to further enhance the adhesive strength of the covering sheet 16. In addition, the aforementioned adhesive extension design could also be applied to the second adhesive tape 28. Preferably, the second adhesive tape 28 could extend inward from the bottom edge E in the second direction D2 to partially overlap the front panel glass G of the OLED panel 12 (as shown in FIG. 7). This allows the sheet structure 30, when attached to the second adhesive tape 28, to partially cover the front panel glass G, thereby further improving the covering and decorative effect of the covering component 24.

In summary, compared with the prior art adopting the adhesive attaching design in which the front covering sheet is directly attached to the flexible circuit board by adhesives, the present invention adopts the frame attaching design in which the frame with the notch is disposed at the position corresponding to the bottom edge of the OLED panel for providing the attachment space avoiding the flexible circuit board, so as to achieve the effect that the covering component is only attached to the frame by planar tape adhesion without contacting the flexible circuit board. In such a manner, the present invention not only solve the prior art problem that the direct adhesive attaching design cannot ensure uniform adhesive distribution over the front covering sheet and causes adhesive overflow and potential damage to the flexible circuit board during removal of the front covering sheet for maintenance. Thus, the present invention can significantly enhance the attachment strength and assembly/disassembly convenience of the covering sheet on the OLED display device and reduce the maintenance cost of the covering sheet.

It should be mentioned that the support plate and the second adhesive tape could be omissible components to simplify the covering sheet design of the present invention. For example, in another embodiment in which the support plate 26 and the second adhesive tape 28 are omitted, the sheet structure 30 could be directly attached to the first adhesive tape 22 as shown in FIG. 5 to cover the bottom edge E of the OLED panel 12 and the flexible circuit board 14. As for other designs (e.g., the adhesive reinforcement design and the front panel glass covering design) in this embodiment, the related description could be reasoned by analogy according to the aforesaid embodiments and omitted herein.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An OLED display device comprising:
an OLED panel;
at least one flexible circuit board electrically connected to the OLED panel for controlling image display of the OLED panel, the at least one flexible circuit board extending outward from a bottom edge of the OLED panel in a first direction, wherein the first direction is perpendicular to a normal direction of the OLED panel; and
a covering sheet comprising:
a frame disposed at a position corresponding to the bottom edge, the frame avoiding the at least one flexible circuit board to form a notch, to make the flexible circuit board contained in the notch and make the frame not overlapped with the at least one flexible circuit board in the normal direction of the OLED panel;
a first adhesive tape attached to the frame and matching a shape of the frame; and
a covering component attached to the first adhesive tape to cover the bottom edge and the at least one flexible circuit board.

2. The OLED display device of claim 1, wherein the first adhesive tape extends toward an area of the bottom edge not occupied by the at least one flexible circuit board to form a reinforcement adhesive area, the first adhesive tape and the reinforcement adhesive area at least partially surround the at least one flexible circuit board, and the covering component is attached to the first adhesive tape and the reinforcement adhesive area.

3. The OLED display device of claim 2, wherein the OLED panel comprises a front panel glass adjacent to the bottom edge, the reinforcement adhesive area extends inward in a second direction opposite to the first direction to partially overlap the front panel glass, and the covering component is attached to the first adhesive tape and the reinforcement adhesive area to cover the bottom edge and the at least one flexible circuit board and partially cover the front panel glass.

4. The OLED display device of claim 1, wherein the covering component comprises:
a support plate attached to the first adhesive tape to cover the at least one flexible circuit board;
a second adhesive tape attached to the support plate; and
a sheet structure attached to the second adhesive tape to cover the bottom edge and the at least one flexible circuit board.

5. The OLED display device of claim 4, wherein the first adhesive tape extends toward an area of the bottom edge not occupied by the at least one flexible circuit board to form a reinforcement adhesive area, the first adhesive tape and the reinforcement adhesive area at least partially surround the at least one flexible circuit board, and the support plate is attached to the first adhesive tape and the reinforcement adhesive area.

6. The OLED display device of claim 4, wherein the OLED panel comprises a front panel glass adjacent to the bottom edge, the second adhesive tape extends inward from the bottom edge in a second direction opposite to the first direction to partially overlap the front panel glass, and the sheet structure is attached to the second adhesive tape to partially cover the front panel glass.

7. The OLED display device of claim 1, wherein the at least one flexible circuit board is bent from the bottom edge toward a back surface of the OLED panel to form a folded board portion and is attached to the back surface.

8. The OLED display device of claim 1, wherein the OLED display device further comprises a back plate containing the OLED panel, and the frame is disposed on the back plate at a position corresponding to the bottom edge.

9. A covering sheet applied to covering at least one flexible circuit board of an OLED display device, the at least one flexible circuit board extending outward from a bottom edge of an OLED panel of the OLED display device in a first direction perpendicular to a normal direction of the OLED panel, the covering sheet comprising:
a frame disposed at a position corresponding to the bottom edge, the frame avoiding the at least one flexible circuit board to form a notch, to make the at least one flexible circuit board contained in the notch and make the frame not overlapped with the at least one flexible circuit board in the normal direction;
a first adhesive tape attached to the frame and matching a shape of the frame; and
a covering component attached to the first adhesive tape to cover the bottom edge and the at least one flexible circuit board.

10. The covering sheet of claim 9, wherein the first adhesive tape extends toward an area of the bottom edge not occupied by the at least one flexible circuit board to form a reinforcement adhesive area, the first adhesive tape and the reinforcement adhesive area at least partially surround the at least one flexible circuit board, and the covering component is attached to the first adhesive tape and the reinforcement adhesive area.

11. The covering sheet of claim 10, wherein the OLED panel comprises a front panel glass adjacent to the bottom edge, the reinforcement adhesive area extends inward in a second direction opposite to the first direction to partially overlap the front panel glass, and the covering component is attached to the first adhesive tape and the reinforcement adhesive area to cover the bottom edge and the at least one flexible circuit board and partially cover the front panel glass.

12. The covering sheet of claim 9, wherein the covering component comprises:
a support plate attached to the first adhesive tape to cover the at least one flexible circuit board;
a second adhesive tape attached to the support plate; and
a sheet structure attached to the second adhesive tape to cover the bottom edge and the at least one flexible circuit board.

13. The covering sheet of claim 12, wherein the first adhesive tape extends toward an area of the bottom edge not occupied by the at least one flexible circuit board to form a reinforcement adhesive area, the first adhesive tape and the reinforcement adhesive area at least partially surround the at least one flexible circuit board, and the support plate is attached to the first adhesive tape and the reinforcement adhesive area.

14. The covering sheet of claim 12, wherein the OLED panel comprises a front panel glass adjacent to the bottom edge, the second adhesive tape extends inward from the bottom edge in a second direction opposite to the first direction to partially overlap the front panel glass, and the sheet structure is attached to the second adhesive tape to partially cover the front panel glass.
